(19) United States
(12) Patent Application Publication
(10) Pub. No.: US 2014/0126665 A1
(43) Pub. Date: May 8, 2014

(54) OUTPUT DRIVER WITH ADJUSTABLE VOLTAGE SWING

(71) Applicant: ATI TECHNOLOGIES ULC, Markham (CA)

(72) Inventor: Chihou Lee, Stouffville (CA)

(73) Assignee: ATI Technologies ULC, Markham (CA)

(21) Appl. No.: 13/669,498

(22) Filed: Nov. 6, 2012

(51) Int. Cl. H03K 5/08; H04B 1/04

(52) U.S. Cl. 375/295; 327/318

(57) ABSTRACT

A system adjusts a voltage swing of an output driver based on a supply voltage. A supply voltage monitor generates a digital code indicating the difference between the supply voltage and nominal voltage representing a preferred level for the supply voltage. An impedance controller sets the voltage swing for the output driver based on the digital code, thereby keeping the voltage swing of the output driver output signal within specified limits while maintaining an impedance match with a load coupled to the output driver.

### FIELD OF THE DISCLOSURE

The present disclosure relates output drivers for communication links.

### BACKGROUND

Processing systems typically employ one or more output drivers to drive signals carrying information to a receiving device, such as a display, via a communication link. Output drivers typically fall into one of two categories: current mode drivers or voltage mode drivers, with voltage mode drivers generally having better power efficiency. For high-speed communication links (e.g. links having baud rates above 2 gigabits per second) the output signal integrity of a voltage driver depends on matching the voltage driver's intrinsic impedance with the characteristic impedance of the load. In voltage mode drivers, the voltage swing of the output signal depends upon the driver's intrinsic impedance and on the supply voltage of the output driver. Variations in the supply voltage and the intrinsic impedance can cause the voltage swing of the output signal to vary beyond the boundaries established by a signal communication specification, thereby causing signal interpretation errors at the receiving device. Conventional systems employ a voltage regulator to limit variations in the supply voltage, but such a voltage regulator consumes significant circuit area and power and typically demands a complex analog design.

### BRIEF DESCRIPTION OF THE DRAWINGS

The present disclosure may be better understood, and its numerous features and advantages made apparent to those skilled in the art by referencing the accompanying drawings.

FIG. 1 is a block diagram of a processing system including an output driver in accordance with some embodiments.

FIG. 2 is a circuit diagram of a portion of a signal generator of the output driver of FIG. 1 in accordance with some embodiments.

FIG. 3 is a combined block and circuit diagram of a supply voltage monitor of FIG. 1 in accordance with some embodiments.

FIG. 4 is a combined block and circuit diagram illustrating a variable resistor of the supply voltage monitor of FIG. 3 in accordance with some embodiments.

FIG. 5 is flow diagram of a method of adjusting the voltage swing of a driver in accordance with some embodiments.

FIG. 6 is a flow diagram illustrating a method for designing and fabricating an integrated circuit device implementing at least a portion of a component of a processing system in accordance with some embodiments.

The use of the same reference symbols in different drawings indicates similar or identical items.

### DETAILED DESCRIPTION

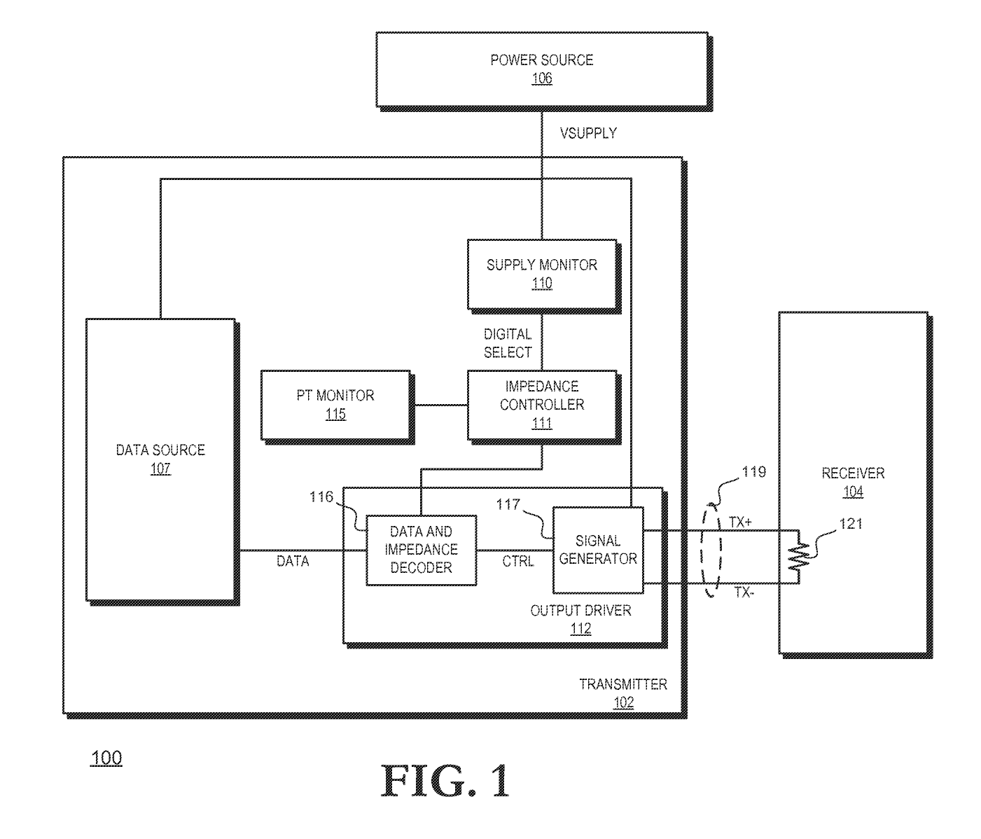

FIGS. 1-6 illustrate techniques for adjusting the voltage swing of a voltage-mode output driver based on a supply voltage, thereby reducing the potential for errors caused by supply voltage variations. The voltage swing is adjusted by adapting the total impedance of the output driver's pull-up and pull-down resistive elements to supply voltage variations. A supply voltage monitor generates a digital code that quantifies the difference between the supply voltage and nominal voltage representing a preferred level for the supply voltage. An impedance controller sets the total impedance of the pull-up and pull-down resistive elements based on the digital code, thereby keeping the voltage swing of the driver output signal within specified limits while maintaining matching of the driver's intrinsic impedance with the load. The impedance controller thus accounts for variations in the supply voltage without requiring the use of a voltage regulator, saving circuit area, power and reducing analog design complexity compared to voltage regulator-based solutions.

FIG. 1 illustrates a block diagram of a processing system 100 in accordance with some embodiments. The processing system 100 includes a transmitting device 102, a receiving device 104, and a power source 106. The transmitting device 102 can be a processor or other device that generates information for transmission via a signal over an interconnect 119. The receiving device 104 can be any device that receives information via a signal, such as a display device (e.g. a computer monitor, television, cell phone display). The power source 106 is a battery, power supply, or other power source that generates a supply voltage, labeled VSUPPLY, for the transmitting device 102.

The transmitting device 102 includes a data source 107 that generates information for transmission. In some embodiments, the data source 107 is one or more processor cores that each includes an instruction pipeline to execute instructions in order to carry out tasks of the processing system 100. The transmitting device 102 can include other components to facilitate execution of the instructions, such as caches, memory interfaces, a northbridge, a southbridge, and the like. In the course of executing instructions or otherwise carrying out its designated tasks, the data source 107 generates a serial stream of information to be transmitted to the receiving device 104. The data source 107 embeds the information in a signal designated “DATA.” In some embodiments, the DATA signal takes the form of a serial stream of digital information that reflects the information to be transmitted.

The output driver 112 is configured to receive the serial stream of information the DATA signal and provide, via the interconnect 119, an output signal to carry the information. In some embodiments, the output driver 112 is a differential signaling driver that transmits the serial stream of information via voltage signals that can be selectively set to either of two voltages, designated V₁ and V₂. The interconnect 119 includes two wires or other signal carrying media designated “TX+” and “TX−.” The receiving device 104 provides a terminator 121 between TX+ and TX−. The output driver 112 transmits bits of the information by applying a voltage of across TX+ and TX− corresponding to the value of the bit of information being transmitted. Thus, for example, to transmit a bit having a digital value of “1”, the output driver sets the voltage across TX+ and TX− to a voltage V₁ and to transmit a bit having a digital value of “0” sets the voltage across TX+ and TX− to a voltage V₂. The difference between V₁ and V₂ is referred to as “voltage swing” and is designated “VSWING” herein. The receiving device 104 is configured to comply with a signal communication protocol that mandates a specified limit on the magnitude of the voltage swing. Accordingly, the output driver 112 is configured to maintain the voltages V₁ and V₂ so that the voltage swing remains within the specified limit.

To set the voltages V₁ and V₂, the output driver 112 modulates pull-up and pull-down resistive elements disposed between a reference node connected to the supply voltage VSUPPLY and a ground reference, whereby the pull-up and pull-down resistive elements determine the impedance of the output driver 112. Accordingly, the swing voltage VSWING depends on the value of the supply voltage VSUPPLY. Conventional systems provide for modulating pull-up and pull-down resistive elements between two fixed sets of resistances to set the voltages V₁ and V₂ respectively. However, in such systems variations in VSUPPLY can cause VSWING to fall outside its specified limit. Accordingly, the transmitting device 102 modifies the voltage swing of the output driver 112 by adjusting the impedance of the pull-up and pull-down resistive elements to account for variations in VSUPPLY.

To this end, the transmitting device 102 includes a supply monitor 110, and an impedance controller 111 to facilitate adjustment of the impedance of the output driver 112 based on variations in VSUPPLY. A Process Temperature (PT) monitor 115 may also be included, in some embodiments. The supply monitor 110 measures VSUPPLY and provides a digital code indicating the difference between the measured VSUPPLY and a nominal value. The nominal value reflects the expected magnitude of VSUPPLY if the power source 106 and the transmitting device 102 are both operating within specified tolerances. The PT monitor 115 provides either process variation information, temperature variation information, or both. Process variation information indicates the variation in behavior at the transmitting device 102. Example process variations may include variations based on the semiconductor process used to form the transmitting device 102, and variations based on how the transmitting device 102 behaves over time as the device ages. Temperature variation information indicates the operating temperature of the transmitting device 102. The impedance controller 111 receives the digital code from the supply monitor 110 and the process variation and/or temperature information from the PT monitor 115 and, based on this information, outputs control information to set the impedance of the pull-up and pull-down resistive elements of the output driver 112. In particular, the control information is configured to set the impedance of the output driver 112 so that VSWING falls within the specified limit and the impedance matches the impedance of the load 121.

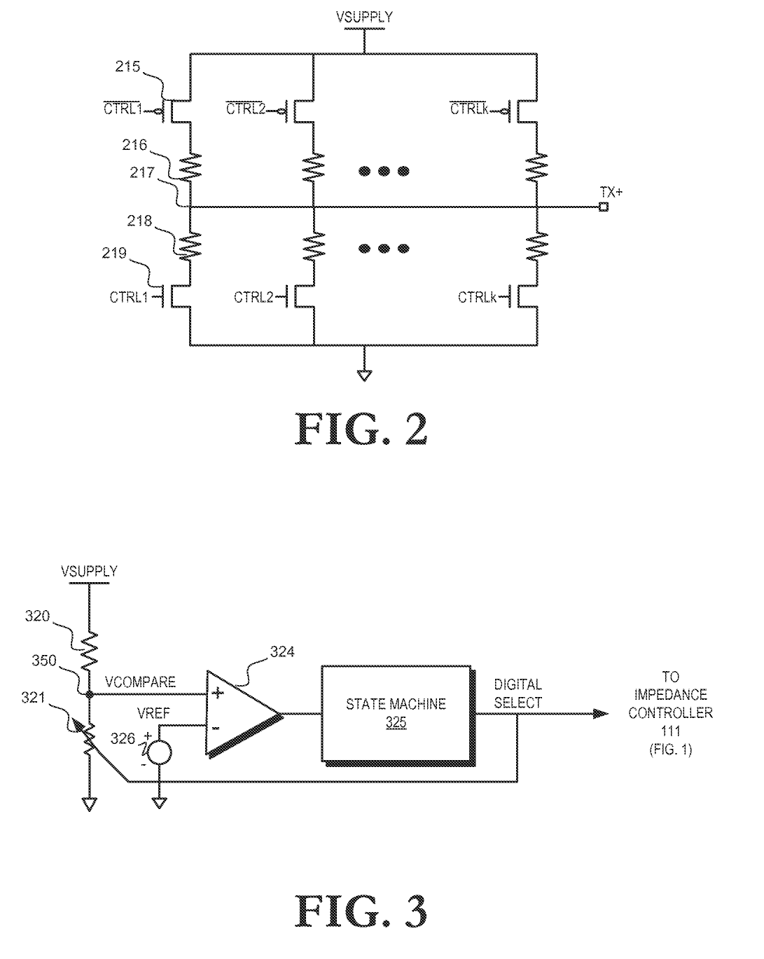

The output driver 112 includes a data and impedance decoder 116 and a signal generator 117. The data and impedance decoder 116 receives the control information from the impedance controller 111 and the DATA signal and, based on the received information, outputs control signaling labeled “CTRL.” The CTRL signaling indicates a value that reflects the next bit of data to be transmitted, as mandated by the DATA signal, and the impedance indicated by the impedance controller 111. The signal generator 117 uses the CTRL signaling to set the voltages at TX+ and TX− to reflect the bit of data to be transmitted and concurrently sets the impedance of the pull-up and pull-down resistive elements of the output driver 112 such that VSWING falls within the specified limit and the impedance matches the impedance of the load 121. In particular, the signal generator uses the CTRL signaling to couple selected sets of resistors between VSUPPLY, TX+, TX−, and the ground reference in order to transmit the information indicated by the DATA signal and to set the impedance for the output driver 112. This can be better understood with reference to FIG. 2.

FIG. 2 depicts a circuit diagram of a portion of the signal generator 117 in accordance with some embodiments. In particular, FIG. 2 illustrates sets of resistive elements (resistors in the illustrated embodiment) connected to a node 217 that is connected to the TX+ wire. The sets of resistors are connected to corresponding transistors that, based on the CTRL signaling, connect selected ones of the resistors between VSUPPLY and the node 217 and connected selected others of the resistors between the node 217 and ground, thereby setting the voltage at the node 217 and the impedance of the output driver 112.

To illustrate, the signal generator 117 includes a set of pull-up transistors (e.g. transistor 215) having a current electrode connected to VSUPPLY, a current electrode connected to a terminal of a corresponding pull-up resistor (e.g. resistor 216), and a control electrode to receive a corresponding control signal of the CTRL signaling. The other terminal of the pull-up resistors are each connected to the node 217. The signal generator 117 also includes a set of pull-down transistors (e.g. transistor 219) having a current electrode connected to the ground reference, a current electrode connected to a terminal of a corresponding pull-down resistor (e.g. resistor 218), and a control electrode to receive a corresponding control signal of the CTRL signaling. The other terminal of the pull-up resistors are each connected to the node 217. In the illustrated embodiment each pull-down transistor receives a control signal that is an inverted representation of a corresponding pull-up transistor.

In addition, the signal generator also includes a similar configuration of pull-up and pull-down transistors and resistors (not shown) connected to a node that supplies a voltage for the TX− wire. This configuration differs from the illustrated configuration in that the control signals are inverted with respect to the control signals depicted at FIG. 2. Thus, for example the configuration connected to the TX− wire includes a transistor and resistor connected similarly to the transistor 315 and the resistor 316, but the transistor receives the signal CTRL₁.

In operation, the data and impedance decoder 116 sets the CTRL signaling to connect the appropriate number of pull-down and pull-up resistors to each of the TX+ and TX− wires so that 1) the voltage across TX+ and TX− reflects the next bit of data indicated by the DATA signal; 2) VSWING does not exceed its specified limit; and 3) the impedance of the output driver 112 matches the load 121. To illustrate, the CTRL signaling modulates the pull-up and pull down resistances between two resistance levels, designated “RHI” and “RLO”, where the values of RHI and RLO depend on VSUPPLY. The following table illustrates the values of each of the pull-down and pull-up resistances for TX+ and TX− depending on the value of the bit being transmitted:

| | Pull-up | Pull-up | Pull-down | Pull-down |
|---|---|---|---|---|
| Bit | resistance | resistance | resistance | resistance |
| Value | (TX+) | (TX−) | (TX+) | (TX−) |
| 0 | RHI | RLO | RLO | RHI |
| 1 | RLO | RHI | RHI | RLO |

The value of RLO can be expressed as follows:

$$RLO = \frac{2 {Z}_{0} {R}_{LO \_ NOM} ( 1 + {V}_{skew} )}{2 {Z}_{0} + {R}_{LO \_ NOM} ( {V}_{skew} )}$$

where Z₀ is the characteristic impedance of the load 121, R_{LO}_{_{—}}_{NOM} is the resistance that would be set assuming that VSUPPLY matches its specified value, and V_{skew} is based on the difference between VSUPPLY and its specified value. RHI can be expressed as follows:

$$RHI = \frac{{R}_{LO \_ NOM} {Z}_{0}}{{R}_{LO \_ NOM} - {Z}_{0}}$$

V_{skew} can be expressed as follows:

$${V}_{skew} = \frac{Δ VSUPPLY}{VSUPPLY\_NOMINAL}$$

where VSUPPLY_NOMINAL is a specified value for VSUPPLY and ΔVSUPPLY is the difference between VSUPPLY as measured by the supply monitor 110 and VSUPPLY_NOMINAL. The data and impedance decoder sets the CTRL signaling to connect the appropriate number of pull-up and pull down resistors to ensure that the above equations are satisfied. In some embodiments, each of the pull-down and pull-up resistors have the same ohmic value, referred to as R_{UNIT}, and the number resistors NLO to achieve a resistance of RLO can be expressed as follows:

$$NLO = \frac{{R}_{UNIT}}{RLO}$$

The number of resistors NHI to achieve a resistance of RHI can be expressed as follows:

$$NHI = \frac{{R}_{UNIT} - {Z}_{0} NLO}{{Z}_{0}}$$

FIG. 3 illustrates a combined block and circuit diagram of the supply monitor 110 in accordance with some embodiments. The supply monitor 110 includes a resistor 320, an adjustable resistor 321, a voltage source 326 a comparator 324, and a state machine 325. The resistor 320 includes a terminal connected to VSUPPLY and a terminal connected to a node 350. The adjustable resistor 321 includes a terminal connected to the node 350, a terminal connected to the ground reference, and a control terminal to receive a signal labeled “DIGITAL SELECT.” The voltage source 326 includes a terminal connected to the ground reference and a terminal to provide a voltage labeled “VREF.” The comparator 324 includes an input connected to the node 350, an input to receive the voltage VREF and an output. The state machine 325 includes an input connected to the output of the comparator 324 and an output to provide the signal DIGITAL SELECT.

The node 350 is set to a voltage labeled “VCOMPARE” based on VSUPPLY and the resistances of resistor 320 and adjustable resistor 321. The voltage source 326 is a stable voltage source, such as a band-gap voltage source, that sets the voltage VREF to be equal to a fraction of VSUPPLY_NOMINAL, such as one-half of VSUPPLY_NOMINAL. The comparator 324 thus provides an indication of the difference between VSUPPLY and VSUPPLY_NOMINAL. In some embodiments, the comparator 324 provides an asserted signal in response to VCOMPARE being greater than VREF and a negated signal in response to VCOMPARE being less than VREF.

The state machine 325 is configured to set the DIGITAL SELECT signal based on the output of the comparator 324. Thus, for example, the state machine 325 can increase the level of the DIGITAL SELECT signal in response to the output of the comparator 324 being asserted and reduce the level of the DIGITAL SELECT signal in response to the output of the comparator 324 being negated. The DIGITAL SELECT signal adjusts the resistance of the adjustable resistor 321. This feedback loop causes the state machine 325 to adjust the resistance of the adjustable resistor 321, by adjusting the DIGITAL SELECT signal, until VCOMPARE is approximately equal to VREF. Once these values are approximately equal, the feedback loop enters a stable state and the DIGITAL SELECT signal level represents the difference between VSUPPLY and VSUPPLY_NOMINAL. Accordingly, the impedance controller 111 uses the level of the digital select signal to set the voltage swing for the output driver 112.

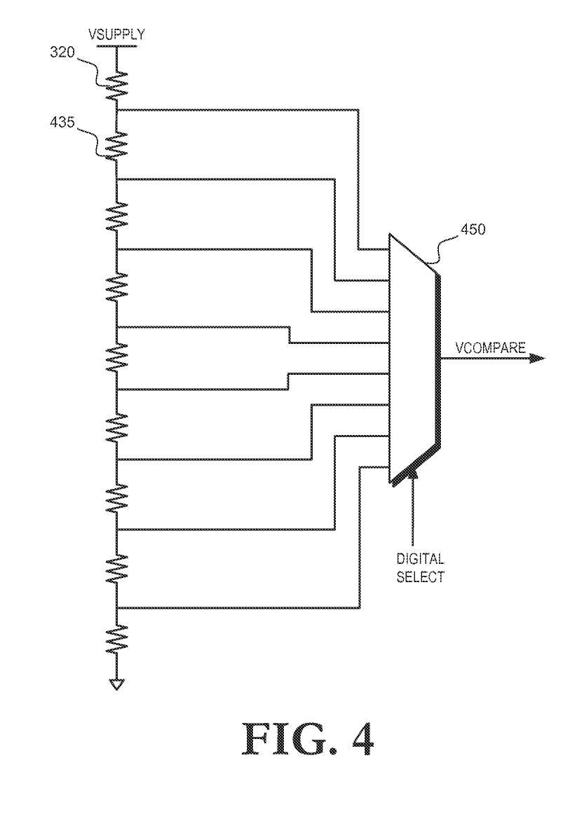

FIG. 4 illustrates an implementation of the resistor 320 and the adjustable resistor 321 in accordance with some embodiments. In the illustrated example, the adjustable resistor 321 is implemented using a resistor chain including a set of resistors 435 of substantially equal resistance connected between the resistor 320 and the ground reference. A multiplexer 450 includes a number of inputs, with each input tapping off one of the resistors in the chain. The multiplexor 450 uses the DIGITAL SELECT signal to select one of the inputs, thereby setting the voltage VCOMPARE. The following table illustrates an example configuration of the illustrated resistor chain, showing the V_{skew} and divider ratio associated with each input of the multiplexer 450:

| DIGITAL | MUX Output | Resistor | Voltage as a % | |
|---|---|---|---|---|
| SELECT | Selected | Divider Ratio | of VSUPPLY | VSKEW |
| 000 | VR0 | 0.81 | 55.2% | 10.5% |
| 001 | VR1 | 0.86 | 53.7% | 7.5% |
| 010 | VR2 | 0.91 | 52.2% | 4.5% |
| 011 | VR3 | 0.97 | 50.7% | 1.5% |
| 100 | VR4 | 1.03 | 49.3% | −1.5% |
| 101 | VR5 | 1.09 | 47.8% | 4.5% |
| 110 | VR6 | 1.16 | 46.3% | −7.5% |
| 111 | VR7 | 1.23 | 44.8% | −10.5% |

Accordingly, when the signal DIGITAL SELECT has reached a stable value, it provides an indication of VSKEW, and therefore comprises a digital code that indicates the difference between VSUPPLY and VSUPPLY_NOMINAL.

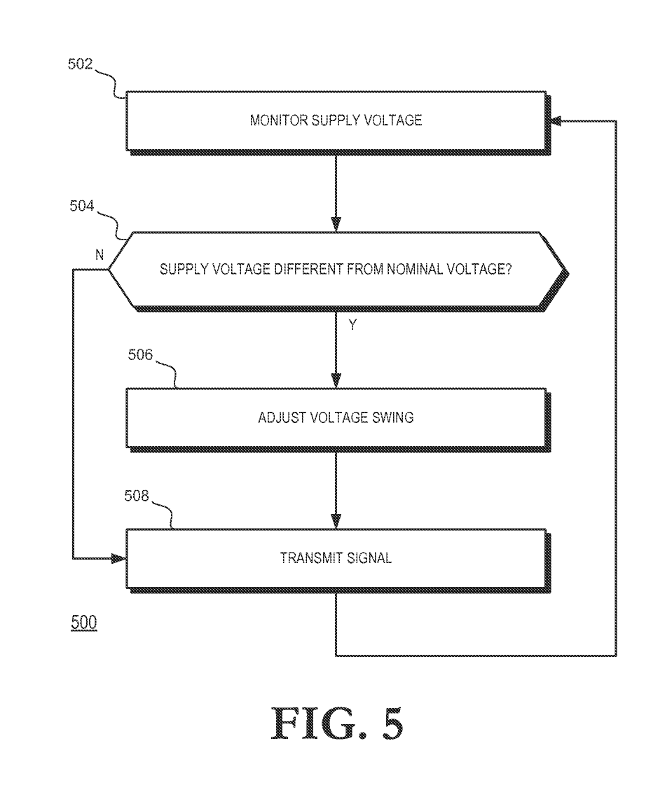

FIG. 5 illustrates a flow diagram of a method 500 of setting an impedance at an output driver in accordance with some embodiments. For purposes of illustration, the method 500 is described with respect to an example implementation at the processing system 100 of FIG. 1. At block 502, the supply monitor 110 monitors VSUPPLY and provides the digital code DIGITAL SELECT. At block 504 the impedance controller 111 determines, based on DIGITAL SELECT, any variation between VSUPPLY and VSUPPLY_NOMINAL. If there is no variation, the impedance controller 111 does not make any adjustment to the impedance of the pull-up and pull-down resistive elements of the output driver 112. Accordingly, the method flow moves to block 508 and the output driver transmits its output signal over the interconnect 119. Returning to block 504, if the impedance controller 111 determines that VSUPPLY differs from VSUPPLY_NOMINAL, the method flow proceeds to block 506 and the impedance controller 111 adjusts the impedance of the pull-up and pull-down resistive elements of the output driver 112 as described above. In particular, the impedance controller 111 adjusts the impedance to account for the variation between VSUPPLY and VSUPPLY_NOMINAL, and to ensure that the impedance of the output driver 112 matches the impedance of the load 121.

In some embodiments, the apparatus and techniques described above are implemented in a system comprising one or more integrated circuit (IC) devices (also referred to as integrated circuit packages or microchips), such as the processing system described above with reference to FIGS. 1-5. Electronic design automation (EDA) and computer aided design (CAD) software tools may be used in the design and fabrication of these IC devices. These design tools typically are represented as one or more software programs. The one or more software programs comprise code executable by a computer system to manipulate the computer system to operate on code representative of circuitry of one or more IC devices so as to perform at least a portion of a process to design or adapt a manufacturing system to fabricate the circuitry. This code can include instructions, data, or a combination of instructions and data. The software instructions representing a design tool or fabrication tool typically are stored in a computer readable storage medium accessible to the computing system. Likewise, the code representative of one or more phases of the design or fabrication of an IC device may be stored in and accessed from the same computer readable storage medium or a different computer readable storage medium.

A computer readable storage medium may include any storage medium, or combination of storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

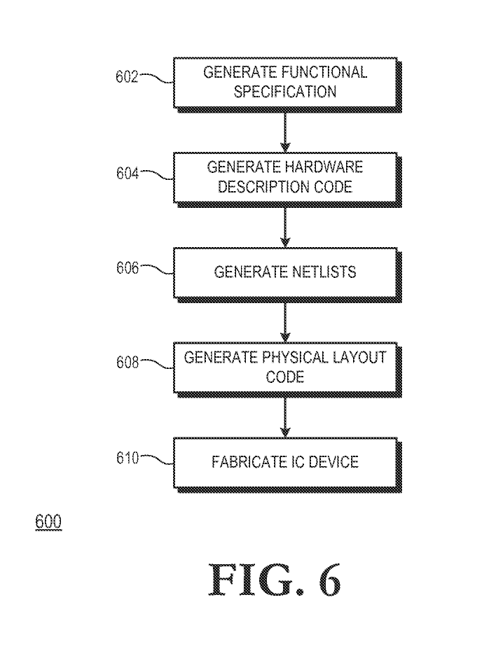

FIG. 6 is a flow diagram illustrating an example method 600 for the design and fabrication of an IC device implementing one or more aspects of the present disclosure. As noted above, the code generated for each of the following processes is stored or otherwise embodied in computer readable storage media for access and use by the corresponding design tool or fabrication tool.

At block 602 a functional specification for the IC device is generated. The functional specification (often referred to as a micro architecture specification (MAS)) may be represented by any of a variety of programming languages or modeling languages, including C, C++, SystemC, Simulink, or MATLAB.

At block 604, the functional specification is used to generate hardware description code representative of the hardware of the IC device. In some embodiments, the hardware description code is represented using at least one Hardware Description Language (HDL), which comprises any of a variety of computer languages, specification languages, or modeling languages for the formal description and design of the circuits of the IC device. The generated HDL code typically represents the operation of the circuits of the IC device, the design and organization of the circuits, and tests to verify correct operation of the IC device through simulation. Examples of HDL include Analog HDL (AHDL), Verilog HDL, SystemVerilog HDL, and VHDL. For IC devices implementing synchronized digital circuits, the hardware descriptor code may include register transfer level (RTL) code to provide an abstract representation of the operations of the synchronous digital circuits. For other types of circuitry, the hardware descriptor code may include behavior-level code to provide an abstract representation of the circuitry's operation. The HDL model represented by the hardware description code typically is subjected to one or more rounds of simulation and debugging to pass design verification.

After verifying the design represented by the hardware description code, at block 606 a synthesis tool is used to synthesize the hardware description code to generate code representing or defining an initial physical implementation of the circuitry of the IC device. In some embodiments, the synthesis tool generates one or more netlists comprising circuit device instances (e.g., gates, transistors, resistors, capacitors, inductors, diodes, etc.) and the nets, or connections, between the circuit device instances. Alternatively, all or a portion of a netlist can be generated manually without the use of a synthesis tool. As with the hardware description code, the netlists may be subjected to one or more test and verification processes before a final set of one or more netlists is generated.

Alternatively or in addition to synthesis, a schematic editor tool can be used to draft a schematic of circuitry of the IC device and a schematic capture tool then may be used to capture the resulting circuit diagram and to generate one or more netlists (stored on a computer readable media) representing the components and connectivity of the circuit diagram. The captured circuit diagram may then be subjected to one or more rounds of simulation for testing and verification.

At block 608, one or more EDA tools use the netlists produced at block 906 to generate code representing the physical layout of the circuitry of the IC device. This process can include, for example, a placement tool using the netlists to determine or fix the location of each element of the circuitry of the IC device. Further, a routing tool builds on the placement process to add and route the wires needed to connect the circuit elements in accordance with the netlist(s). The resulting code represents a three-dimensional model of the IC device. The code may be represented in a database file format, such as, for example, the Graphic Database System II (GDSII) format. Data in this format typically represents geometric shapes, text labels, and other information about the circuit layout in hierarchical form.

At block 610, the physical layout code (e.g., GDSII code) is provided to a manufacturing facility, which uses the physical layout code to configure or otherwise adapt fabrication tools of the manufacturing facility (e.g., through mask works) to fabricate the IC device. That is, the physical layout code may be programmed into one or more computer systems, which may then control, in whole or part, the operation of the tools of the manufacturing facility or the manufacturing operations performed therein.

In some embodiments, certain aspects of the techniques described above may implemented by one or more processors of a processing system executing software. The software comprises one or more sets of executable instructions that, when executed by the one or more processors, manipulate the one or more processors to perform one or more aspects of the techniques described above. The software is stored or otherwise tangibly embodied on a computer readable storage medium accessible to the processing system, and can include the instructions and certain data utilized during the execution of the instructions to perform the corresponding aspects.

In some embodiments, certain aspects of the techniques described above may implemented by one or more processors of a processing system executing software. The software comprises one or more sets of executable instructions stored on a computer readable medium that, when executed by the one or more processors, manipulate the one or more processors to perform one or more aspects of the techniques described above. The software is stored or otherwise tangibly embodied on a computer readable storage medium accessible to the processing system, and can include the instructions and certain data utilized during the execution of the instructions to perform the corresponding aspects.

As disclosed herein, in some embodiments a method includes: transmitting an output signal via an output driver; and concurrent with transmitting the output signal, adjusting a voltage swing of the output driver based on a change in a supply voltage of the output driver. In some aspects, adjusting the voltage swing includes adjusting a total impedance of pull-up and pull-down resistive elements of the output driver so that an impedance of the output driver matches an impedance of a load. In some aspects, adjusting the voltage swing includes: generating a compare voltage based on the supply voltage; and adjusting the voltage swing of the output driver based on a difference between the compare voltage and a reference voltage. In some aspects generating the compare voltage includes generating the compare voltage with a resistor chain disposed between the supply voltage reference and a ground reference. In some aspects, the method includes adjusting a resistance of the resistor divider based on the difference between the compare voltage and the reference voltage. In some aspects, adjusting the voltage swing of the output driver includes coupling a number of resistors to a node of the output driver based on the supply voltage of the output driver. In some aspects the method includes adjusting the voltage swing of the output driver based on semiconductor process variations and/or temperature variations at an integrated circuit that incorporates the output driver.

In some embodiments, a method includes determining a digital code based on a supply voltage of an output driver; setting a voltage swing of the output driver based on the digital code; and communicating a signal via an output of the output driver, a voltage swing of the signal based on the voltage swing of the output driver. In some aspects determining the digital code includes: generating a compare voltage based on the supply voltage; and determining the digital code based on a difference between the compare voltage and a reference voltage. In some aspects generating the compare voltage includes generating the compare voltage with a resistor chain disposed between a supply voltage reference and a ground reference. In some aspects the method includes adjusting a resistance of the resistor divider based on the digital code. In some aspects setting the voltage swing of the output driver includes coupling a number of resistors to a node of the output driver based on the supply voltage of the output driver, the number of resistors based on the digital code. In some aspects the method includes adjusting the voltage swing of the output driver based on semiconductor process and/or temperature variations at an integrated circuit that incorporates the output driver.

In some embodiments a device includes an output driver to drive an output signal based on received data; a supply voltage monitor to determine a supply voltage of the output driver; and an impedance controller to set a voltage swing of the output driver based on the supply voltage. In some aspects the impedance controller is to set the impedance of the output driver based on an impedance of a load to be coupled to the output driver. In some aspects the supply voltage monitor includes: a comparator to determine a difference between a compare voltage based on the supply voltage to a reference voltage; a state machine to determine a digital code based on the difference between the compare voltage and the reference voltage; and the impedance controller is to set the voltage swing of the output driver based on the digital code. In some aspects the supply voltage monitor further includes a resistor divider disposed between a supply voltage reference and a ground reference to generate the compare voltage. In some aspects the resistor divider includes an adjustable resistor having a resistance based on the digital code. In some aspects the device includes a plurality of resistors coupleable to a node of the output driver via a corresponding plurality of transistors; and wherein the impedance controller sets the voltage swing of the output driver by coupling a selected number of the plurality of resistors to the node based on the supply voltage. In some aspects the impedance controller sets the voltage swing of the output driver based on semiconductor process and/or temperature variations at the device.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed.

Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

What is claimed is:

1. A method, comprising:
transmitting an output signal via an output driver; and
concurrent with transmitting the output signal, adjusting a voltage swing of the output driver based on a change in a supply voltage of the output driver.

2. The method of claim 1, wherein adjusting the voltage swing comprises adjusting a total impedance of pull-up and pull-down resistive elements of the output driver so that an impedance of the output driver matches an impedance of an interconnect that carries the output signal.

3. The method of claim 1, wherein adjusting the voltage swing comprises:
generating a compare voltage based on the supply voltage; and
adjusting the voltage swing of the output driver based on a difference between the compare voltage and a reference voltage.

4. The method of claim 3, wherein generating the compare voltage comprises generating the compare voltage with a resistor chain disposed between the supply voltage reference and a ground reference.

5. The method of claim 4, further comprising adjusting a resistance of the resistor divider based on the difference between the compare voltage and the reference voltage.

6. The method of claim 1, wherein adjusting the voltage swing of the output driver comprises coupling a number of resistors to a node of the output driver based on the supply voltage of the output driver.

7. The method of claim 1, further comprising adjusting the voltage swing of the output driver based on at least one of semiconductor process variations and temperature variations at an integrated circuit that incorporates the output driver.

8. A method, comprising:
determining a digital code based on a supply voltage of an output driver;
setting a voltage swing of the output driver based on the digital code; and
communicating a signal via an output of the output driver, a voltage swing of the signal based on the voltage swing of the output driver.

9. The method of claim 8, wherein determining the digital code comprises:
generating a compare voltage used on the supply voltage; and
determining the digital code based on a difference between the compare voltage and a reference voltage.

10. The method of claim 9, wherein generating the compare voltage comprises generating the compare voltage with a resistor chain disposed between a supply voltage reference and a ground reference.

11. The method of claim 10, further comprising adjusting a resistance of the resistor divider based on the digital code.

12. The method of claim 8, wherein setting the voltage swing of the output driver comprises coupling a number of resistors to a node of the output driver based on the supply voltage of the output driver, the number of resistors based on the digital code.

13. The method of claim 8, further comprising adjusting the voltage swing of the output driver based on at least one of semiconductor process and temperature variations at an integrated circuit that incorporates the output driver.

14. A device, comprising:
an output driver to drive an output signal based on received data;
a supply voltage monitor to determine a supply voltage of the output driver; and
an impedance controller to set a voltage swing of the output driver based on the supply voltage.

15. The device of claim 14, wherein the impedance controller is to set the impedance of the output driver based on an impedance of a load coupled to the output driver.

16. The device of claim 14, wherein the supply voltage monitor comprises:
a comparator to determine a difference between a compare voltage based on the supply voltage to a reference voltage;
a state machine to determine a digital code based on the difference between the compare voltage and the reference voltage; and
wherein the impedance controller is to set the voltage swing of the output driver based on the digital code.

17. The device of claim 16, wherein the supply voltage monitor further comprises a resistor divider disposed between a supply voltage reference and a ground reference to generate the compare voltage.

18. The device of claim 17, wherein the resistor divider includes an adjustable resistor having a resistance based on the digital code.

19. The device of claim 14, further comprising:
a plurality of resistors coupleable to a node of the output driver via a corresponding plurality of transistors; and
wherein the impedance controller sets the voltage swing of the output driver by coupling a selected number of the plurality of resistors to the node based on the supply voltage.

20. The device of claim 14, wherein the impedance controller sets the voltage swing of the output driver based on at least one of semiconductor process and temperature variations at the device.
